(19) United States
(12) Patent Application Publication
(10) Pub. No.: US 2024/0030823 A1
(43) Pub. Date: Jan. 25, 2024

(54) PACKAGE APPLIED TO A FLYBACK POWER CONVERTER

(71) Applicant: Leadtrend Technology Corp., Hsinchu County (TW)

(72) Inventors: Tzu-Chen Lin, Hsinchu County (TW); Chu-Jui Chen, Hsinchu County (TW); Ming-Chang Tsou, Hsinchu County (TW)

(73) Assignee: Leadtrend Technology Corp., Hsinchu County (TW)

(21) Appl. No.: 17/949,177

(22) Filed: Sep. 20, 2022

(30) Foreign Application Priority Data
Jul. 21, 2022 (TW) 111127368

(51) Int. Cl. H02M 3/335; H01L 23/495

(52) U.S. Cl. CPC H02M 3/33523; H01L 23/49575

(57) ABSTRACT

A package applied to a flyback power converter includes a first lead frame and a second lead frame. The first lead frame connects to at least one component of a primary side of the flyback power converter. An isolation distance exists between the first lead frame and the second lead frame. The primary side of the flyback power converter is galvanically isolated from and communicates with a secondary side of the flyback power converter through capacitive coupling effect between the first lead frame and the second lead frame.

### BACKGROUND OF THE INVENTION

### 1. Field of the Invention

The present invention relates to a package applied to a flyback power converter, and particularly to the package can utilize capacitive coupling effect of a lead frame to make a primary side of the flyback power converter be galvanically isolated from and communicate with a secondary side of the flyback power converter.

### 2. Description of the Prior Art

In the prior art, a primary side of a flyback power converter is galvanically isolated from and communicates with a secondary side of the flyback power converter through an optocoupler, wherein the optocoupler is composed of a light-emitting diode and a bipolar transistor.

However, the optocoupler will increase cost of the flyback power converter, so how to reduce the cost of the flyback power converter is an important issue for a designer of the flyback power converter.

### SUMMARY OF THE INVENTION

An embodiment of the present invention provides a package applied to a flyback power converter. The package includes a first lead frame and a second lead frame. The first lead frame connects to at least one component of a primary side of the flyback power converter. An isolation distance exists between the first lead frame and the second lead frame. The primary side of the flyback power converter is galvanically isolated from and communicates with a secondary side of the flyback power converter through capacitive coupling effect between the first lead frame and the second lead frame.

Another embodiment of the present invention provides a package applied to a flyback power converter. The package includes a lead frame, wherein the lead frame at least includes two coupling parts, and one side of a primary side and a secondary side of the flyback power converter is galvanically isolated from and communicates with another side of the primary side and the secondary side of the flyback power converter through capacitive coupling effect between the lead frame and the flyback power converter.

The present invention provides a package applied to a flyback power converter. The package utilizes capacitive coupling effect of a lead frame to make a primary side of the flyback power converter be galvanically isolated from and communicate with a secondary side of the flyback power converter. Therefore, compared to the prior art, because the present invention does not need an optocoupler, the present invention can reduce cost of the flyback power converter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a top view of a package applied to a flyback power converter according to a first embodiment of the present invention.

FIG. 2 is a diagram illustrating a front view of the package.

FIG. 3 is a diagram illustrating the second coupling part and the first coupling part being located on a same planer.

FIG. 4 is a diagram illustrating a coupling part of the two coupling parts and a corresponding part of the flyback power converter forming a capacitor.

### DETAILED DESCRIPTION

Please refer to FIG. 1. FIG. 1 is a diagram illustrating a top view of a package 100 applied to a flyback power converter according to a first embodiment of the present invention, wherein because pins of the package 100 are not a main technical feature of the present invention, the pins of the package 100 are neglected. In addition, in one embodiment of the present invention, a material of the package 100 can be epoxy resin. But, the present invention is not limited to the material of the package 100 being epoxy resin. That is to say, the material of the package 100 can be materials known to those of ordinary skilled in the art. As shown in FIG. 1, the package 100 includes a first lead frame 102 and a second lead frame 104, wherein the first lead frame 102 and the second lead frame 104 are composed of copper. However, the present invention is not limited to the first lead frame 102 and the second lead frame 104 being composed of copper. That is to say, the first lead frame 102 and the second lead frame 104 can be composed of other metals (e.g. an iron-nickel alloy). In addition, as shown in FIG. 1, the first lead frame 102 and the second lead frame 104 are only shown parts corresponding to the present invention. In addition, as shown in FIG. 1, wherein corresponding components 106 (e.g. a primary side winding, a bridge rectifier, a power switch, a primary-side controller, etc.) of the primary side of the flyback power converter and corresponding components 108 (e.g. a secondary winding, a secondary controller, etc.) of the secondary side of the flyback power converter are installed on the first lead frame 102, and the material of the package 100 encompasses the first lead frame 102, the second lead frame 104, the corresponding components 106 of the primary side of the flyback power converter, and the corresponding components 108 of the secondary side of the flyback power converter. In addition, because the corresponding components 106 of the primary side of the flyback power converter and the corresponding components 108 of the secondary side of the flyback power converter are also not a main technical feature of the present invention, the present invention utilizes blocks to represent the corresponding components 106 of the primary side of the flyback power converter and the corresponding components 108 of the secondary side of the flyback power converter. In addition, in another embodiment of the present invention, the corresponding components 106 of the primary side of the flyback power converter is installed on the first lead frame 102 and the corresponding components 108 of the secondary side of the flyback power converter is installed on the second lead frame 104.

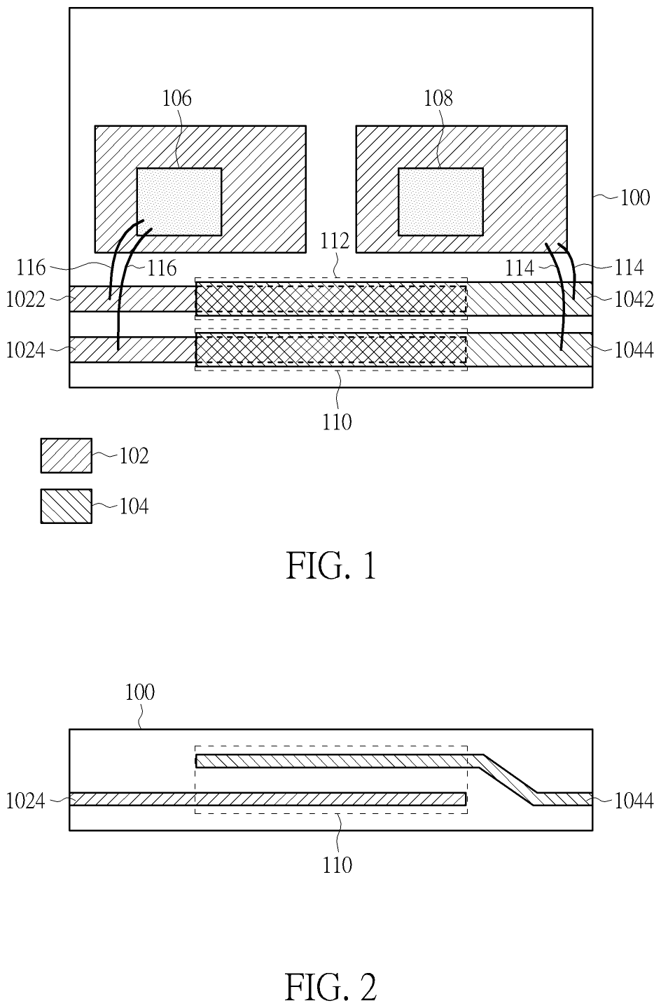

Please simultaneously refer to FIGS. 1, 2. FIG. 2 is a diagram illustrating a front view of the package 100. As shown in FIG. 1, the first lead frame 102 at least includes two first coupling parts 1022, 1024, and the second lead frame 104 at least includes two second coupling parts 1042, 1044, wherein as shown in FIG. 2 (taking the first coupling part 1024 and the second coupling part 1044 as an example), the first coupling part 1024 and the second coupling part 1044 can form a capacitor 110, the second coupling part 1044 is above the first coupling part 1024 (of course, in another embodiment of the present invention, the first coupling part 1024 can be also above the second coupling part 1044), and a predetermined distance (i.e. an isolation distance) should exist between the second coupling part 1044 and the first coupling part 1024 to ensure that no short circuit exists between the second coupling part 1044 and the first coupling part 1024. In addition, in one embodiment of the present invention, the predetermined distance between the second coupling part 1044 and the first coupling part 1024 is not less than 0.3 mm (e.g. the predetermined distance between the second coupling part 1044 and the first coupling part 1024 is equal to 0.5 mm). In addition, in other embodiments of the present invention, an isolation material exists between the second coupling part 1044 and the first coupling part 1024, so the predetermined distance between the second coupling part 1044 and the first coupling part 1024 can be shorten according to a characteristic of the isolation material. In addition, as shown in FIG. 1, the first coupling part 1022 and the second coupling part 1042 can also form a capacitor 112. Therefore, the primary side of the flyback power converter can not only be galvanically isolated from the secondary side of the flyback power converter through the capacitors 110, 112, but can also utilize the capacitors 110, 112 to communicate with the secondary side of the flyback power converter, wherein the capacitors 110, 112 are used for transmitting/receiving differential signals to increase noise immunity of the flyback power converter. In addition, as shown in FIG. 1, the corresponding components 108 of the secondary side of the flyback power converter are electrically connected to the second coupling parts 1042, 1044 through a wire 114, and the corresponding components 106 of the primary side of the flyback power converter are electrically connected to the first coupling parts 1022, 1024 through a wire 116.

In addition, in another embodiment of the present invention, the material of the package 100 (e.g. epoxy resin) is filled between the first coupling part 1024 and the second coupling part 1044 (between the first coupling part 1022 and the second coupling part 1042). Taking the first coupling part 1024 and the second coupling part 1044 as an example, if a dielectric constant of the material of the package 100 is between 4 and 4.4, an overlapping area between the first coupling part 1024 and the second coupling part 1044 is equal to 6 mm*0.5 mm, and the predetermined distance between the second coupling part 1044 and the first coupling part 1024 is equal to 0.5 mm, a capacitance of the capacitor 110 is about equal to 0.23 pF. In addition, in another embodiment of the present invention, insulating glue (or a support member) exists between the first coupling part 1024 and the second coupling part 1044 (also between the first coupling part 1022 and the second coupling part 1042).

In addition, the present invention is not limited to the second coupling part 1044 being above the first coupling part 1024. That is to say, in another embodiment of the present invention, as shown in FIG. 3, the second coupling part 1044 and the first coupling part 1024 are located on a same planer, and the capacitor 110 exists between a side of the second coupling part 1044 and a side of the first coupling part 1024.

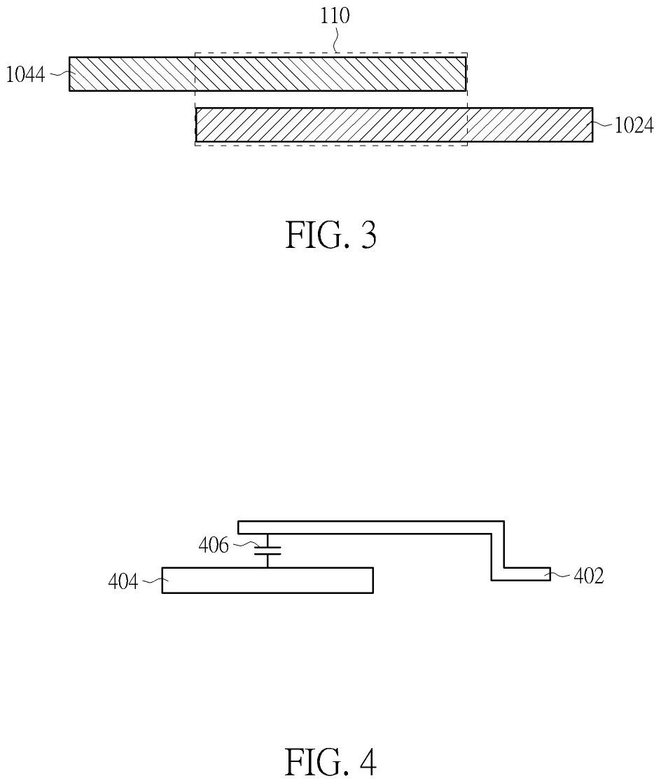

In addition, in a second embodiment of the present invention, a difference between a package (not shown in FIG. 4) of the second embodiment of the present invention and the package 100 is that the package of the second embodiment of the present invention only includes a lead frame, wherein the lead frame at least includes two coupling parts. As shown in FIG. 4, a coupling part 402 of the two coupling parts and a corresponding part 404 of the flyback power converter form a capacitor 406, wherein the corresponding part 404 can be located at the primary side of the flyback power converter or the secondary side of the flyback power converter, the coupling part 402 can be above the corresponding part 404, and a predetermined distance between the coupling part 402 and the corresponding part 404 is not less than 0.3 mm (e.g. the predetermined distance between the coupling part 402 and the corresponding part 404 is equal to 0.5 mm). Therefore, the primary side of the flyback power converter can not only be galvanically isolated from the secondary side of the flyback power converter through two capacitors formed by the two coupling parts and two corresponding parts of the flyback power converter, but can also utilize the two capacitors formed by the two coupling parts and the two corresponding parts of the flyback power converter to communicate with the secondary side of the flyback power converter. In addition, subsequent operational principles of the second embodiment of the present invention can be referred to those of the package 100, so further description thereof is omitted for simplicity.

In addition, the present invention is not limited to configurations shown in FIGS. 2, 4. That is, any configuration that the primary side of the flyback power converter is galvanically isolated from and communicates with the secondary side of the flyback power converter through capacitive coupling effect within the package falls within the scope of the present invention.

To sum up, the package provided by the present invention utilizes capacitive coupling effect of a lead frame to make the primary side of the flyback power converter be galvanically isolated from and communicate with the secondary side of the flyback power converter. Therefore, compared to the prior art, because the present invention does not need the optocoupler, the present invention can reduce the cost of the flyback power converter.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package applied to a flyback power converter, comprising:
a first lead frame connecting to at least one component of a primary side of the flyback power converter; and
a second lead frame, wherein an isolation distance exists between the first lead frame and the second lead frame, and the primary side of the flyback power converter is galvanically isolated from and communicates with a secondary side of the flyback power converter through capacitive coupling effect between the first lead frame and the second lead frame.

2. The package of claim 1, wherein the first lead frame and the second lead frame are composed of copper.

3. The package of claim 1, wherein the first lead frame at least comprises two first coupling parts, the second lead frame at least comprises two second coupling parts, and each first coupling part and a corresponding second coupling part form a capacitor.

4. The package of claim 3, wherein the primary side of the flyback power converter is galvanically isolated from and communicates with the secondary side of the flyback power converter through two capacitors formed by the two first coupling parts and the two second coupling parts.

5. The package of claim 3, wherein a material of the package is filled between the each first coupling part and the corresponding second coupling part.

6. The package of claim 3, wherein the corresponding second coupling part is above the each first coupling part.

7. The package of claim 3, wherein the corresponding second coupling part and the each first coupling part are located on a same planer.

8. The package of claim 3, wherein insulating glue exists between the each first coupling part and the corresponding second coupling part.

9. The package of claim 3, wherein a support member exists between the each first coupling part and the corresponding second coupling part.

10. The package of claim 3, wherein a distance between the each first coupling part and the corresponding second coupling part is not less than 0.3 mm.

11. The package of claim 1, wherein corresponding components of the primary side of the flyback power converter and corresponding components of the secondary side of the flyback power converter are installed on the first lead frame, a material of the package encompasses the first lead frame, the second lead frame, the corresponding components of the primary side of the flyback power converter, and the corresponding components of the secondary side of the flyback power converter.

12. The package of claim 1, wherein corresponding components of the primary side of the flyback power converter are installed on the first lead frame, corresponding components of the secondary side of the flyback power converter are installed on the second lead frame, and a material of the package encompasses the first lead frame, the second lead frame, the corresponding components of the primary side of the flyback power converter, and the corresponding components of the secondary side of the flyback power converter.

13. A package applied to a flyback power converter, comprising:
a lead frame at least comprising two coupling parts, wherein one side of a primary side and a secondary side of the flyback power converter is galvanically isolated from and communicates with another side of the primary side and the secondary side of the flyback power converter through capacitive coupling effect between the lead frame and the flyback power converter.

14. The package of claim 13, wherein each coupling part of the two coupling parts and a corresponding part of the flyback power converter form a capacitor.

15. The package of claim 14, wherein the each coupling part is above the corresponding part.

16. The package of claim 14, wherein a distance between the each coupling part and the corresponding part is not less than 0.3 mm.

17. The package of claim 13, wherein the one side of the primary side of the flyback power converter is galvanically isolated from and communicates with the another side of the primary side and the secondary side of the flyback power converter through two capacitors formed by the two coupling parts and two corresponding parts of the flyback power converter.

18. The package of claim 13, wherein corresponding components of the primary side of the flyback power converter and corresponding components of the secondary side of the flyback power converter are installed on the lead frame, and a material of the package encompasses the lead frame, the corresponding components of the primary side of the flyback power converter, and the corresponding components of the secondary side of the flyback power converter.
